(19) United States
(12) Patent Application Publication
(10) Pub. No.: US 2005/0205940 A1
(43) Pub. Date: Sep. 22, 2005

(54) Semiconductor device and method for manufacturing the same

(75) Inventor: Fumio Ootsuka, Ibaraki-ken (JP)

Correspondence Address: LEYDIG VOIT & MAYER, LTD, 700 THIRTEENTH ST. NW, SUITE 300, WASHINGTON, DC, 20005-3960, US

(73) Assignee: Semiconductor Leading Edge Technologies, Inc., Tsukuba-shi (JP)

(21) Appl. No.: 11/003,484

(22) Filed: Dec. 6, 2004

(30) Foreign Application Priority Data
Mar. 17, 2004 (JP) 2004-076978
Sep. 28, 2004 (JP) 2004-282180

(51) Int. Cl. H01L 29/45; H01L 29/74; H01L 31/111; H01L 29/76; H01L 29/94; H01L 31/062; H01L 31/113; H01L 31/119

(52) U.S. Cl. 257/374; 257/392

(57) ABSTRACT

In a semiconductor device having a first transistor and a second transistor, the first transistor includes a first gate electrode composed of a first material having a first work function, and a first gate insulating film. The second transistor includes a second gate electrode composed of a second material having a second work function, and a second gate insulating film. The first gate insulating film includes a high-dielectric-constant film, and a first insulating film on the high-dielectric-constant film. In the second gate insulating film, after removing the first gate electrode, the first insulating film on the high-dielectric-constant film is removed.

### BACKGROUND OF THE INVENTION

1. Field of the Invention

The present invention relates to a semiconductor device and a method for manufacturing a semiconductor device. More specifically, the present invention relates to a semiconductor device having a dual metal gate structure including a plurality of gate electrodes formed from materials having different work functions, and a method for manufacturing such a semiconductor device.

2. Background Art

With the miniaturization and high integration of semiconductor devices in recent years, the thickness of a gate insulating film has been increasingly reduced. However, the reduction of the thickness of a gate insulating film causes the problem of depletion of the gate electrode. Therefore, an MISFET (metal insulator semiconductor field effect transistor) having a metal gate electrode using a metal as the gate electrode has attracted attention.

On the other hand, with the diversification and high integration of semiconductor devices, a CMISFET (complementary MISFET; hereafter referred to as CMIS) wherein both an n-type MISFET (hereafter referred to as n-MIS) and a p-type MISFET (hereafter referred to as p-MIS) are mounted on a semiconductor has been used. In the CMIS, the lowering of threshold voltage (roll of f) has become marked concurrent with miniaturization. Therefore, a dual-gate structure wherein the gate electrode of the n-MIS is n-type and the gate electrode of the p-MIS is p-type has been used (e.g., refer to Japanese Patent Application Laid-Open No. 2003-258121).

For example, when polycrystalline silicon is used as the material for a gate electrode, the dual-gate structure can be easily formed by ion implantation of an n-type impurity into the gate electrode of an n-MIS and a p-type impurity into the gate electrode of a p-MIS.

When a metal gate is used as the gate electrode, gate electrodes using different metal materials must be separately formed for the n-MIS and the p-MIS. For example, the material for the gate electrode has a work function of 4.6 eV or less, preferably 4.3 eV or less, for the gate electrode of the n-MIS; and a work function of 4.6 eV or more, preferably 4.9 eV or more, for the gate electrode of the p-MIS.

However, when dual-metal gates using different metal materials are separately formed for the n-MIS and the p-MIS, for example, the step is required wherein after forming gate electrodes in the both regions for the n-MIS and for the p-MIS using a material for the gate electrode of the n-MIS, the gate electrode is removed from the p-MIS region. When the unnecessary gate electrode is thus removed, the underlying gate insulating film may be damaged. Therefore, it is considered that the mobility in the transistor lowers due to the interface state to lower the performance of the transistor.

### SUMMARY OF THE INVENTION

The object of the present invention is to solve the above-described problems, and to provide a semiconductor device having a dual-metal gate for suppressing the damage of a gate insulating film, and a method for manufacturing such a semiconductor device.

According to one aspect of the present invention, a semiconductor device comprises a first transistor and a second transistor. The first transistor includes a first gate electrode composed of a first material having a first work function, and a first gate insulating film. The second transistor includes a second gate electrode composed of a second material having a second work function, and a second gate insulating film. The first gate insulating film includes a high-dielectric-constant film, and a first insulating film formed on the high-dielectric-constant film. The second gate insulating film includes at least the high-dielectric-constant film.

According to other aspect of the present invention, in a method for manufacturing a semiconductor device, first, a high-dielectric-constant film on each of a first active region and a second active region on a substrate. A first insulating film is formed on the high-dielectric-constant film in each of the first and second active region. A first gate electrode composed of a first material having a first work function is formed on the first insulating film on each of the first and second active regions. The first gate electrode formed in the second active region is removed. The first insulating film in the second active region is removed by etching using the first gate electrode as a mask. A second gate electrode composed of a second material having a second work function is formed on the second active region.

According to other aspect of the present invention, in a method for manufacturing a semiconductor device, first, a dummy gate insulating film and a dummy gate electrode are formed on a substrate in each of a first active region and a second active region. An impurity diffusion layer is formed in each of a first active region and a second active region using each of the dummy gate electrode as a mask. An interlayer insulating film embedding the dummy gate insulating films and the dummy gate electrodes is formed. An opening is formed in the interlayer insulating film in each of the first active region and the second active region, by removing the dummy gate insulating films and the dummy gate electrodes from the interlayer insulating film. A high-dielectric-constant film is formed at least in the opening in each of the first active region and the second active region. A first insulating film is formed on the high-dielectric-constant film in each of the first active region and the second active region. A first material having a first work function is embedded in the opening in each of the first active region and the second active region. The first material embedded in the opening in the second active region is removed. The first insulating film formed on the area other than in the opening of the first active region is removed. A second material having a second work function is embedded in the opening of the second active region.

According to other aspect of the present invention, in a method for manufacturing a semiconductor device, first, a gate insulating film including at least a high-dielectric-constant film, and a first insulating film on the high-dielectric-constant film is formed in each of a first active region and a second active region on a substrate. A first gate electrode composed of a material having a first work function is formed on the gate insulating film in each of the first active region and the second active region. An impurity diffusion layer is formed in each of a first active region and a second active region using each of the first gate electrode as a masks. Silicide layers are formed on the surface of the impurity diffusion layers. An interlayer insulating film embedding the first gate insulating films and the first gate electrodes is formed. An opening is formed in the interlayer insulating film in the second active region by removing the first gate electrode of the second active region from the interlayer insulating film. The first insulating film exposed on the bottom of the opening is removed. A second gate electrode composed of a material having a second work function is embedded in the opening.

### BRIEF DESCRIPTION OF THE DRAWINGS

FIG. 1 is a schematic sectional view for illustrating a semiconductor device according to the first embodiment of the present invention;

FIG. 2 is a flow diagram for illustrating a method for manufacturing a semiconductor device according to the first embodiment of the present invention;

FIGS. 3 to 11 are schematic sectional views for illustrating the states in the steps for manufacturing the semiconductor device according to the first embodiment of the present invention;

FIG. 12 is a schematic sectional view for illustrating a semiconductor device 200 according to the second embodiment of the present invention;

FIG. 13 is a flow diagram for illustrating a method for manufacturing a semiconductor device according to the second embodiment of the present invention;

FIGS. 14 to 21 are schematic sectional views for illustrating the states in the steps for manufacturing the semiconductor device according to the second embodiment of the present invention;

FIG. 22 is a schematic sectional view for illustrating a semiconductor device according to the third embodiment of the present invention;

FIG. 23 is a flow diagram for illustrating a method for manufacturing a semiconductor device according to the third embodiment of the present invention;

FIGS. 24 to 31 are schematic sectional views for illustrating the states in the steps for manufacturing the semiconductor device according to the third embodiment of the present invention.

### DETAILED DESCRIPTION OF THE PREFERRED EMBODIMENTS

The embodiments of the present invention will be described below referring to the drawings. In the drawings, the same of corresponding parts are denoted by the same reference numerals and characters, and the description thereof will be simplified or omitted.

When the number, amount and range of elements are mentioned in the description of the embodiments, the present invention is not limited thereto, unless particularly specified, or principally determined. The structures, the steps in the methods and the like described for the embodiments are not necessarily essential for the present invention unless particularly specified, or principally determined.

### First Embodiment

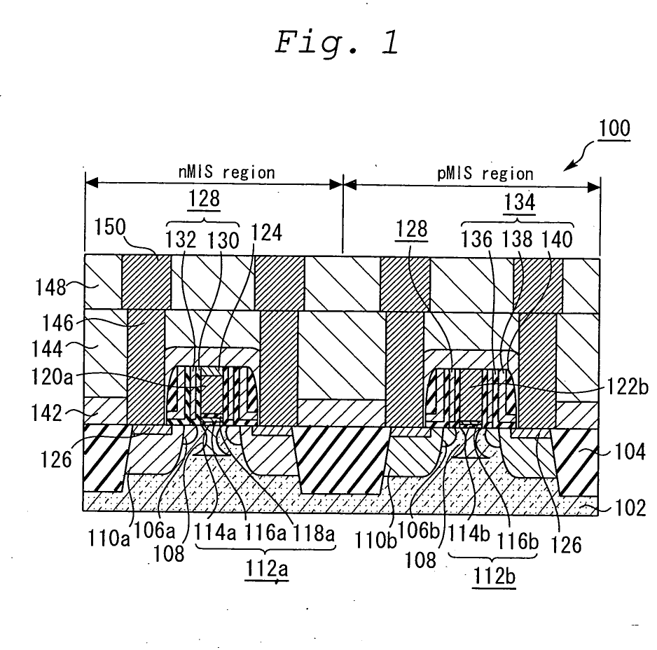

FIG. 1 is a schematic sectional view for illustrating a semiconductor device according to the first embodiment of the present invention.

As FIG. 1 illustrates, the semiconductor device 100 in the first embodiment is a CMIS having an n-MIS and a p-MIS, and has a dual-metal-gate structure. The structure of the semiconductor device 100 will be specifically described below. In this specification, the region wherein the n-MIS is formed is referred to as the n-MIS region, and the region wherein the p-MIS is formed is referred to as the p-MIS region, for the simplification of description.

In the cross section illustrated in FIG. 1, STIs (shallow trench isolations) 104 are formed on a substrate 102 to divide the substrate 102 into an n-MIS region and a p-MIS region. N-type extensions 106a and p-type extensions 106b are formed in the n-MIS region and p-MIS region, respectively. The extensions 106a and 106b are impurity-diffusion layers each having a relatively low concentration and a shallow junction. A pocket 108 is formed so as to surround the underside of each of the extensions 106a and 106b. n-type source-drain regions 110a and p-type source-drain regions 110b are formed on the both side of the extensions 106a and 106b, respectively. The source-drain regions 110a and 110b are impurity-diffusion layers each having a relatively high concentration and a deep junction.

In the n-MIS region, a gate insulating film 112a is formed on the channel portion between the extensions 106a on the substrate 102. The gate insulating film 112a is composed of an SiO₂ film 114a immediately on the substrate 102, an HfSiO film 116a formed on the SiO₂ film 114a, and an SiN film 118a laminated further on the HfSiO film 116a. The thickness of the SiO₂ film 114a is about 0.8 nm, the thickness of the HfSiO film 116a is about 2 nm, and the thickness of the SiN film 118a is about 0.5 nm.

In the p-MIS region, a gate insulating film 112b is formed on the channel portion between the extensions 106b on the substrate 102. The gate insulating film 112b is composed of an SiO₂ film 114b immediately on the substrate 102, and an HfSiO film 116b laminated thereon. The thickness of the SiO₂ film 114b is about 0.8 nm, and the thickness of the HfSiO film 116a is about 2 nm. The gate insulating film 112b in the p-MIS region differs from the gate insulating film 112a in the n-MIS region in that the HfSiO film 116b is the uppermost layer, and no SiN film is formed on the HfSiO film 116b.

In the n-MIS region, a gate electrode 120a is formed on the gate insulating film 112a. The gate electrode 120a is a poly-Si gate wherein As and Hf are diffused. The work function of the gate electrode 120a is about 4.1 eV. On the other hand, in the p-MIS region, a gate electrode 122b is formed on the gate insulating film 112b. The gate electrode 122b is a metal-gate electrode made of W, whose work function is about 4.7 to 4.9 eV.

On the surfaces of the gate electrode 120a in the n-MIS region, and the surface of the source-drain regions 110a and 110b in the n-channel and p-channel regions, NiSi films 124 and 126 are formed in self-aligning manner.

In each of n-MIS and p-MIS regions, a spacer 128 is formed on the sides of the gate electrodes 120a and 122b and the gate insulating films 112a and 112b. The spacer 128 is composed of an SiO₂ film 130 contacting the sides of the gate electrodes 120a and 122b, and an SiN film 132 contacting the SiO₂ film 130.

On the both sides of the spacer 128, spacers 134 are formed. The spacer 134 is composed of an SiO₂ film 136 formed on the portion contacting the spacer 128, an SiN film 138 formed on the outside the SiO₂ film 136, and an SiO₂ film 140 formed on the side of SiN film 138.

An SiN film 142 and an SiO₂ film 144 are formed so as to embed the gate electrodes 120a and 122b, and the spacers 128 and 134. Through the SiN film 142 and the SiO₂ film 144, contact plugs 146 connected to the source-drain regions 110a and 110b are formed. On the SiO₂ film 144, an interlayer insulating film 148 is further formed, and through the interlayer insulating film 148, Cu wirings 150 connected to the contact plugs 146 are formed.

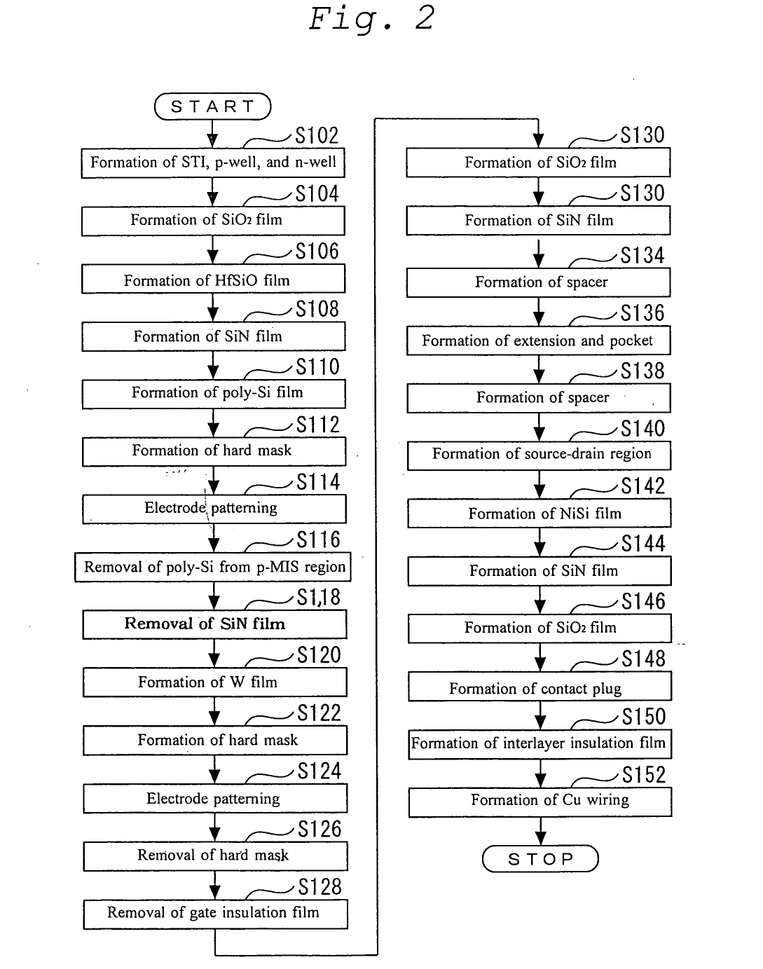

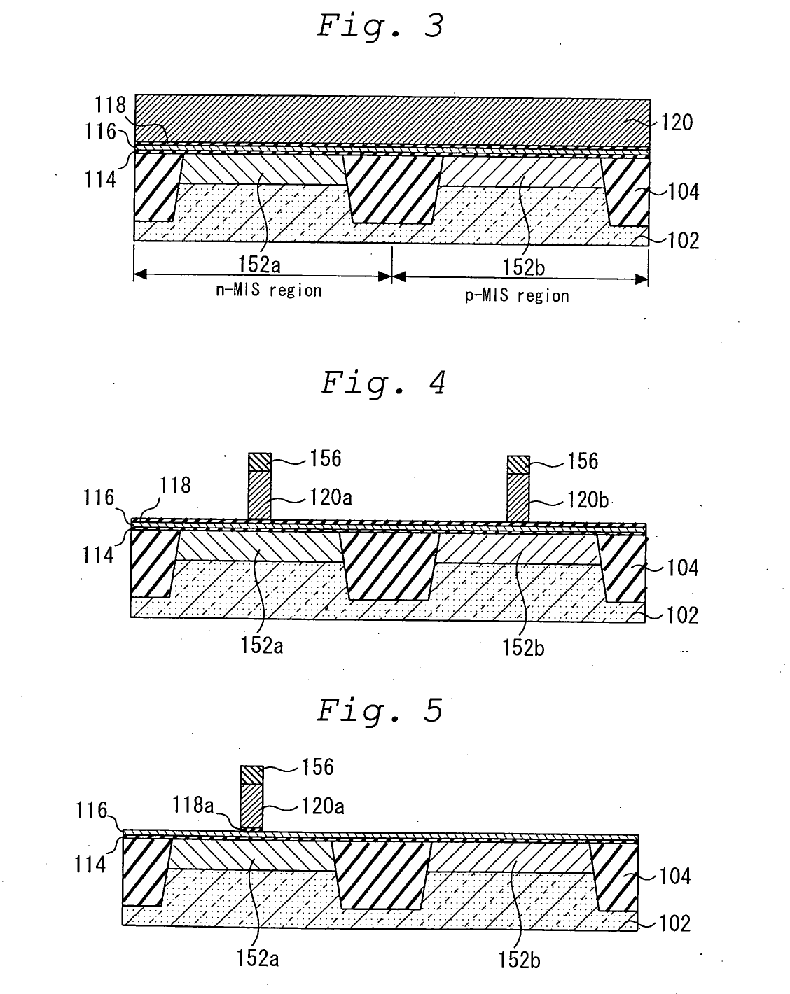

FIG. 2 is a flow diagram for illustrating a method for manufacturing a semiconductor device according to the first embodiment of the present invention. FIGS. 3 to 11 are schematic sectional views for illustrating the states in the steps for manufacturing the semiconductor device 100.

The method for manufacturing the semiconductor device according to the first embodiment of the present invention will be specifically described referring to FIGS. 1 to 11.

First, as FIG. 3 illustrates, after forming STIs 104 are formed on the substrate 102, B (boron) ions and P (phosphorus) ions are implanted into the n-MIS region and p-MIS region isolated by the STIs 104, respectively, to form a p-well 152a and an n-well 152b, respectively (Step S102).

Next, using thermal oxidation, an SiO₂ film 114 is formed (Step S104). The thickness of the SiO₂ film 114 is about 0.8 nm. Thereafter, an HfSiO film 116 is formed on the SiO₂ film 114 (Step S106). The HfSiO film 116 is formed using MOCVD (metal organic chemical vapor deposition) so as to have a thickness of about 2 nm. Thereafter, an SiN film 118 is formed on the HfSiO film 116 (Step S108). The SiN film 118 is formed using CVD (chemical vapor deposition) so as to have a thickness of about 0.5 nm.

Next, a poly-Si film 120 is formed on the SiN film 118 (Step S110). The poly-Si film 120 is formed using CVD so as to have a thickness of about 120 nm.

Next, as FIG. 4 illustrates, a hard mask 156 for etching is formed on the poly-Si film 120 (Step S112). Here, an SiO₂ film having a thickness of about 30 nm is first formed. Thereafter, a resist mask is formed using lithography on the portion of the SiO₂ film where the gate electrodes 120a and 122b are formed, and the SiO₂ film is etched using the resist mask as the mask to form the hard mask 156 composed of the SiO₂ film.

Next, the poly-Si film 120 is patterned to form the gate electrodes 120a and 120b (Step S114). Here, the poly-Si film 120 is etched using the hard mask 156 as the mask to form the pattern for the desired gate electrodes.

Next, as FIG. 5 illustrates, the gate electrode (poly-Si film) 120b and the hard mask 156 in the p-MIS-region side are removed (Step S116). When the gate electrode 120b is removed, a resist mask is formed so as to shield the n-MIS-region side, and then only the gate electrode 120b in the p-MIS-region side is removed.

When the gate electrode 120b in the p-MIS-region side is removed, the SiN film 118 is damaged. Therefore, as FIG. 5 shows, after removing the gate electrode 120b, only the SiN film 118a immediately under the gate electrode 120a in the n-MIS-region side is left, and the SiN film 118 on other areas is removed using wet etching (Step S118). At this time, the SiN film 118 can be selectively removed without damaging the underlying HfSiO film 116 by wet etching.

Next, a W film is formed (Step S120). The W film is formed on the entire surface of the substrate using CVD. Thereafter, a hard mask 158 is formed on the W film (Step S122). In the same manner as described above, after forming the SiO₂ film, a resist mask is formed on the locations to form the gate electrodes 122b using lithography, and the SiO₂ film is etched using the resist mask as the mask to form the hard mask 158 having the desired pattern.

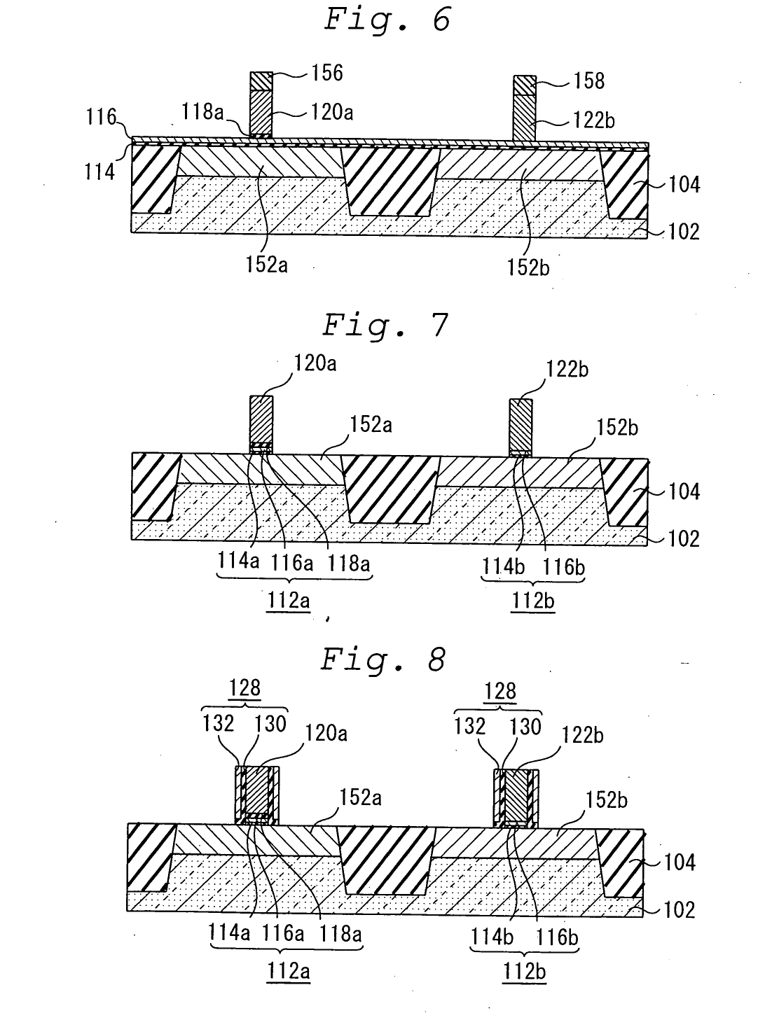

Next, as FIG. 6 illustrates, the W film is etched using the hard mask 158 as the mask to form the gate electrode 122b (Step S124).

Next, as FIG. 7 illustrates, the hard masks 156 and 158 are removed using wet etching (Step S126), and the HfSiO film 116 and the SiO₂ film 114 on the areas other than the area shielded by the gate electrodes 120a and 122b are removed (Step S128).

Next, SiO₂ films 130 are formed (Step S130). The SiO₂ films 130 are formed using CVD so as to have a thickness of about 2 nm evenly on the entire surfaces of the gate electrodes 120a and 122b. Thereafter, SiN films 132 are formed on the entire surfaces thereof (step S132), and etched back to form spacers 128 on the sides of the gate electrodes 120a and 122b, and the gate insulating films 112a and 112b as FIG. 8 illustrates (Step S134).

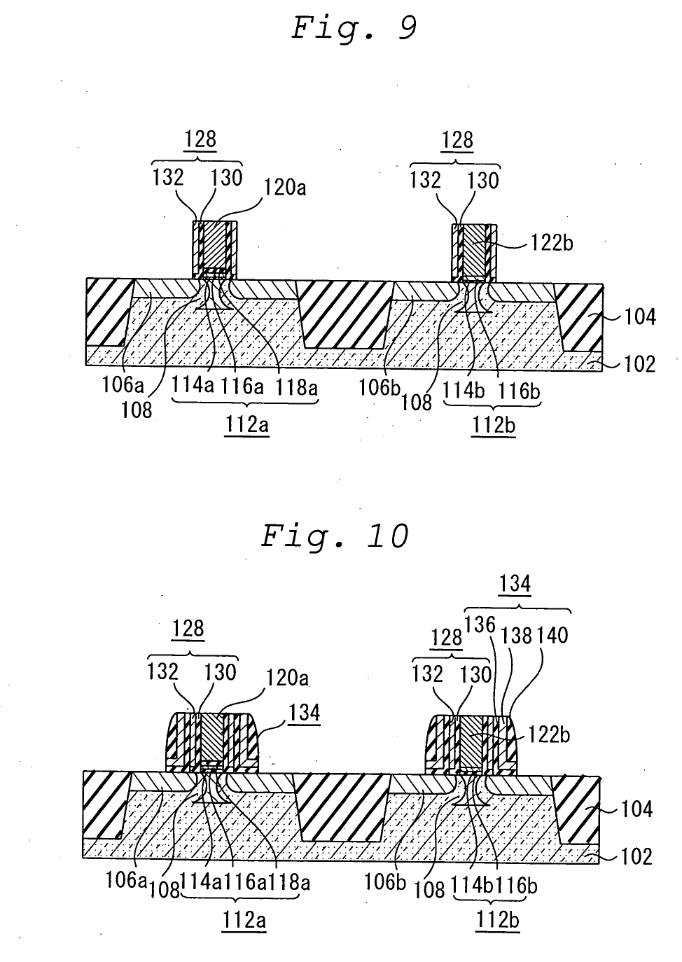

Next, as FIG. 9 illustrates, extensions 106a, 106b, and pockets 108 are formed (Step S136). Here, the p-MIS region is first shielded with a resist, As ions are implanted using the gate electrode 120a and the spacer 128 in the n-MIS region as masks, and then B ions are implanted. Thereby, the extension 106a and the pocket 108 are formed in the n-MIS-region side. Similarly, a mask shielding the n-MIS-region side is formed, and B ions are implanted using the gate electrode 122b and the spacer 128 in the p-MIS region as masks, to form the extension 106b, and As ions are implanted to form the pocket 108.

Next, as FIG. 10 illustrates, spacers 134 are formed so as to contact the sides of the spacers 128 formed on the sides of the gate electrodes 120a and 122b in the n-MIS and p-MIS regions (Step S138). Here, an SiO₂ film 136, an SiN film 138, and an SiO₂ film 140 are first deposited in this order on the entire surface including the gate electrodes 120a, 122b, and the spacer 128. Thereafter, the SiO₂ film 140 and the SiN film 138 are sequentially etched back, and the SiO₂ film 136 is wet-etched. Thereby, the spacers 134 are formed only on the sides of the spacers 128 on the sides of the gate electrodes 120a and 122b.

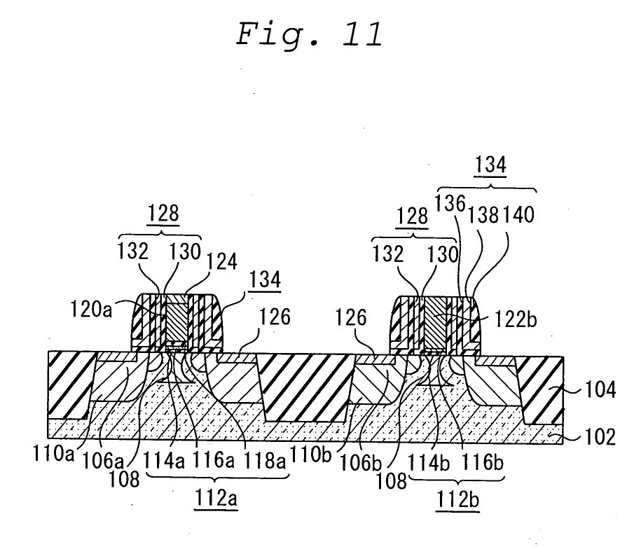

Thereafter, as FIG. 11 illustrates, the source-drain regions 110a and 110b are formed in the n-MIS and p-MIS regions, respectively (Step S140). Here, a resist film shielding the p-MIS region is first formed for masking, and then As ions are implanted using the gate electrode 120a, the spacers 128 and 134 in the n-MIS region and the resist film as masks. Thereafter, a resist film shielding then-MIS region is first formed for masking, and B ions are implanted using the gate electrode 122b, the spacers 128 and 134 in the p-MIS region and the resist film as masks. Here, heat treatment for activating impurities is also performed. Thereby, the source-drain regions 110a and 110b, which are high-concentration impurity-diffusion layers having a relatively deep junction and a high implanted impurity concentration can be formed.

Next, NiSi layers 124 and 126 are formed on the surfaces of the source-drain regions 110a and 110b and the surface of the gate electrode 120a (Step S142). Here, Si is allowed to react with Ni by forming an Ni layer on the entire surface of the substrate and performing heat treatment to form NiSi layers 124 and 126 in self-aligning manner. Thereafter, the Ni layer left without reacting is removed.

Next, an SiN film 142 and an SiO₂ film 144 are formed (Steps S144 and S146). Here, the SiN film 142 plays a role as the etching stopper when contact holes are formed. Thereafter, through the SiO₂ film 144 and the SiN film 142, contact plugs 146 connected to the NiSi film 126 are formed (Step S148). Here, contact holes are first formed so as to run through the SiO₂ film 144 and the SiN film 142, and to expose the surface of the NiSi layer 126 at the bottoms thereof. Then W is embedded in the holes, and the surface thereof is planarized using CMP to form contact plugs 146 running through the SiO₂ film 144 and the SiN film 142.

Thereafter, as required, an interlayer insulating film 148 is formed on the SiO₂ film 144 (Step S150). Cu wirings 150 are formed in required positions of the interlayer insulating film 148 (Step S152). Thereby, the semiconductor device 100 as illustrated in FIG. 1 can be formed. As required, an interlayer insulating film, wirings and the like are formed on the interlayer insulating film 148 to form a semiconductor device having a multilayer structure.

In the first embodiment, as described above, an SiN film 118 is previously formed on the HfSiO film 116 as a gate insulating film. Then, when the gate electrode 120b composed of poly-Si formed in the p-MIS-region side is removed (Step S116), the SiN film 118 is made to function as the etching stopper film. Thereafter, the SiN film 118 on the unnecessary area is removed (Step S118). Thereby, the SiN film 118 damaged during the removal of the gate electrode 120b is removed, and the gate electrode 122b in the p-MIS region can be formed thereon using no-damaged HfSiO film 116b as a gate insulating film. Thereby, a transistor having gate insulating films 112a and 112b having good film quality can be easily formed in both the n-MIS and p-MIS regions.

In the first embodiment, poly-Si is used as the gate electrode 120a in the n-MIS region. Here, in the poly-Si gate, Hf is diffused from the HfSiO film 116a formed as the underlying layer in the stage of activation, and reacts with Si to form Hf silicide. Thereby, the work function of the gate electrode 120a becomes the n-type work function. For the gate electrode 122b in the p-MIS region, W having a p-type work function is used. Thereby, a CMIS having a dual-metal structure can be realized.

In the first embodiment, the gate insulating film 112b of the p-MIS region is a two-layer laminated structure consisting of an HfSiO film 116b and an underlying SiO₂ film 114b. However, the gate insulating film of the p-MIS region in the present invention is not limited thereto. The gate insulating film may be, for example, a three-layer laminated structure consisting of an SiO₂ film 114b, an HfSiO film 116b, and an SiN film leaving the damaged SiN film 118 thinly without completely removing. Since the damaged portion of the SiN film 118 can also be thereby removed, the film quality of the gate insulating film can be made satisfactory.

In the first embodiment, the case wherein an SiO₂ film 114, an HfSiO film 116, and an SiN film 118 are used as the materials for the gate insulating films 112a and 112b is described. However, the materials for the gate insulating film in the present invention are not limited thereto. For example, the high-dielectric-constant film formed on the SiO₂ film 114 is not limited to an HfSiO film, but other high-dielectric-constant films, such as an HfO film and as HfAlO film, can also be used. Here, however, the use of an Hf-based high-dielectric-constant film is considered to be preferable. This is because the use of the Hf-based high-dielectric-constant film enables the gate electrode in the n-MIS region to be adjusted to have an n-type work function, since Hf is diffused in poly-Si composing the gate electrode 120a, and reacts with Si to form Hf silicide. Alternatively, the upper-layer SiN film 118a can be substituted by other films, such as SiON film.

In the first embodiment, the case wherein poly-Si and W are used for the gate electrodes 120a and 122b of the n-MIS and p-MIS regions, respectively, is described. However, the materials for the gate electrodes in the present invention are not limited thereto, but the gate electrodes may be formed using other materials, as long as the materials have adequate work functions. Specifically, for example, the use of a Ta film for the gate electrode of the n-MIS region, and the use of a TiN film or a laminated film of TiN and W for the gate electrode of the p-MIS region can be considered.

In the present invention, the structures of other portions, such as the structures of the spacers 128 and 134, the upper-layer interlayer insulating film and wirings, and the manufacturing methods for the films are not limited to those described in the first embodiment. These can be appropriately selected as required.

### Second Embodiment

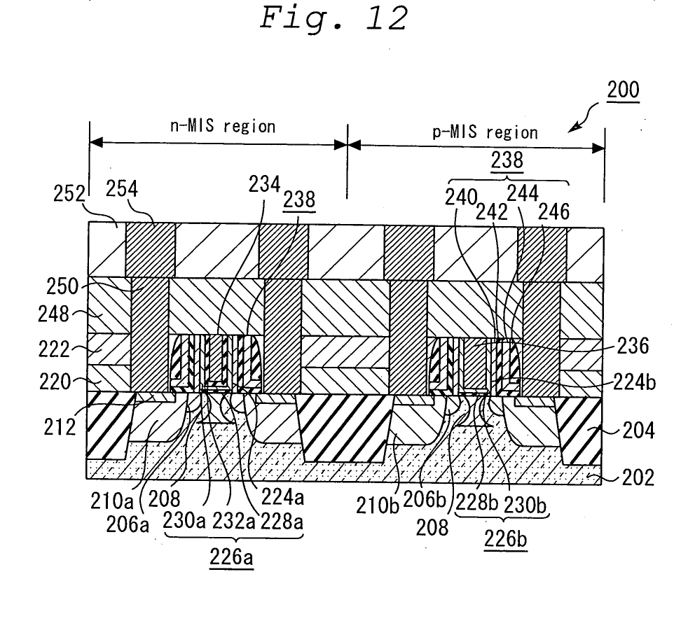

FIG. 12 is a schematic sectional view for illustrating a semiconductor device 200 according to the second embodiment of the present invention.

As FIG. 12 illustrates, the semiconductor device 200 in the second embodiment is similar to the semiconductor device 100 described in the first embodiment. However, the semiconductor device 200 in the second embodiment has a Damascene gate structure, and is manufactured by applying the method for manufacturing the semiconductor device 100 in the first embodiment to the Damascene gate structure.

In the cross section illustrated in FIG. 12, STIs 204 are formed in the substrate 202, and the substrate 202 is divided into an n-MIS region and a p-MIS region similar to the semiconductor device 100. N-type and p-type extensions 206a and 206b, respectively, are formed in the n-MIS region and the p-MIS region, respectively, and pockets 208 are formed so as to surround the undersides of the extensions 206a and 206b. In the both sides of the extensions 206a and 206b, n-type and p-type source-drain regions 210a and 210b are formed, respectively. On the surfaces of the source-drain regions 210a and 210b, NiSi layers 212 are formed.

On the substrate 202, an SiN film 220 and an SiO₂ film 222 are formed. Gate trenches 224a and 224b for forming gate electrodes are formed in the n-MIS region and the p-MIS region, respectively, so as to run through the SiN film 220 and the SiO₂ film 222.

A gate insulating film 226a is formed in a gate trench 224a of the n-MIS region. The gate insulating film 226a is a laminated film consisting of a thin SiO₂ film 228a, an HfSiO film 230a, and an SiN film 232a formed on the inner wall of the gate trench 224a. On the other hand, a gate insulating film 226b is formed in a gate trench 224b of the p-MIS region. The gate insulating film 226b is a laminated film consisting of a thin SiO₂ film 228b and an HfSiO film 230b formed on the inner wall of the gate trench 224b. Here, the thickness of the SiO₂ films 228a and 228b is about 0.8 nm, the thickness of the HfSiO films 230a and 230b is about 2 nm, and the thickness of the SiN film 232a is about 0.5 nm.

In the n-MIS region, a gate electrode 234a is formed on the SiN film 232a in the gate trench 224a. On the other hand, in the p-MIS region, a gate electrode 236b is formed on the HfSiO film 230b in the gate trench 224b. The gate electrode 234a is composed of poly-Si in which As ions and Hf ions are diffused, and has a work function of about 4.1 eV. The gate electrode 236b is composed of W and has a work function of about 4.7 to 4.9 eV.

On the both sides of each of gate trenches 224a and 224b, spacers 238 are formed. Each spacer 238 is composed of an SiN film 240, an SiO₂ film 242, an SiN film 244, and an SiO₂ film 246.

An SiO₂ film 248 is formed on the SiO₂ film 222, and contact plugs 250 running through the SiO₂ film 248, the SiO₂ film 222 and the SiN film 220, and extending to the NiSi layer 212 on the surfaces of the source-drain regions 210a and 210b are formed. An interlayer insulating film 252 is formed on the SiO₂ film 248 as in the first embodiment, and Cu wirings 254 are formed in the required locations.

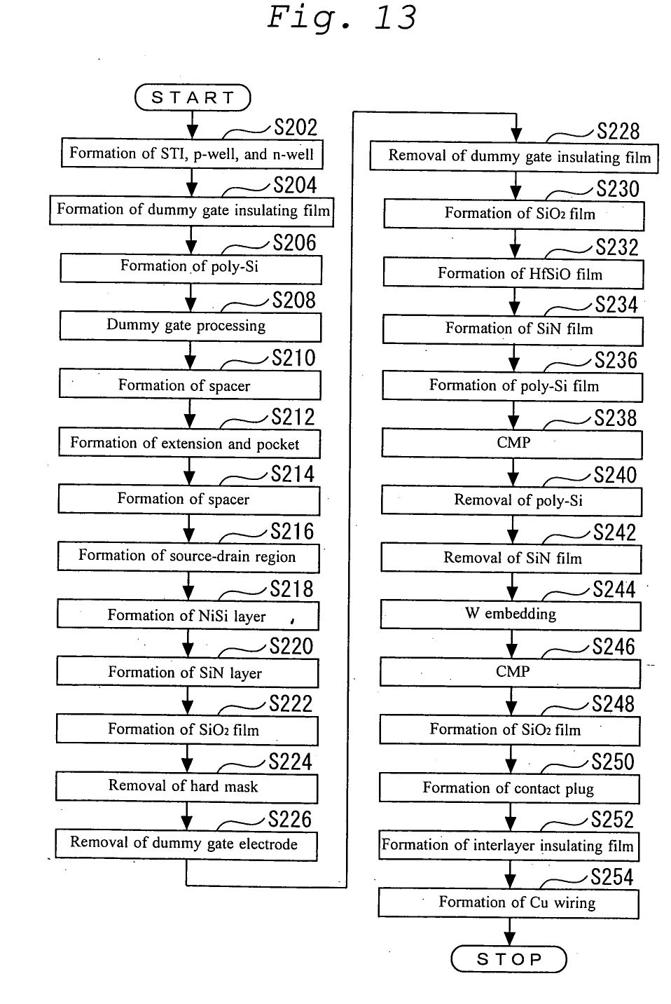

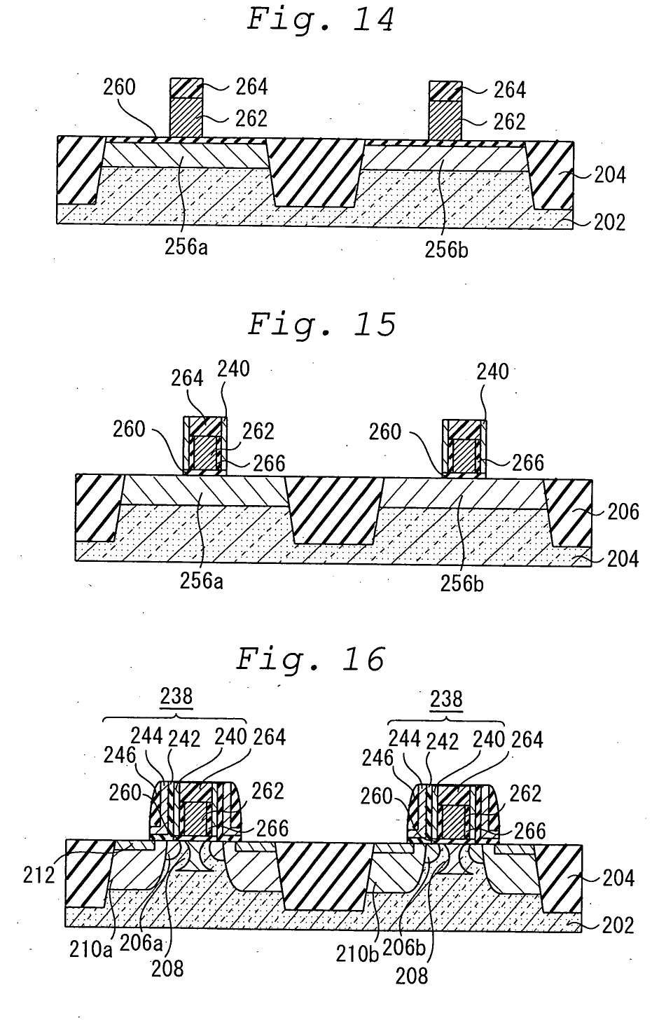

FIG. 13 is a flow diagram for illustrating a method for manufacturing a semiconductor device 200 according to the second embodiment of the present invention. FIGS. 14 to 21 are schematic sectional views for illustrating the states in the steps for manufacturing the semiconductor device 200 in the second embodiment.

The method for manufacturing the semiconductor device 200 according to the second embodiment of the present invention will be specifically described referring to FIGS. 12 to 21.

In the same manner as in the first embodiment, STIs 204, a p-well 256a, and an n-well 256b are formed on a substrate 202 (Step S202), and a dummy gate insulating film 260 is formed on the channel of each region (Step S204). Then, a poly-Si film is formed as the material film for forming dummy gate electrodes 262 (Step S206). Thereafter, as FIG. 14 shows, the dummy gate electrodes 262 are formed (Step S208). Here, for example, SiO₂ films are formed on the poly-Si film. Next, resist masks are formed using lithography on the locations to form gate electrodes, and the SiO₂ films are etched to form hard masks 264 using the resist masks as the masks. The poly-Si film is etched using the hard masks 264 as masks to form the dummy gate electrodes 262.

Next, as FIG. 15 illustrates, spacers consisting of SiO₂ films 266 and SiN films 240 are formed on the sides of the dummy gate electrodes 262 (Step S210). Here, the SiO₂ films 266 of a thickness of about 2 nm and the SiN films 240 of a thickness of about 10 nm are deposited, and etched back to leave spacers only on the sides of the dummy gate electrodes 262.

Next, as FIG. 16 illustrates, extensions 206a and 206b, and pockets 208 are formed (Step S212). Here, the p-MIS region is first shielded with a resist, and ions are implanted using the dummy gate electrode 262, the SiO₂ film 266 and the SiN film 240 of the n-MIS region and the resist as masks to form the extension 206a and the pocket 208 in the n-MIS region. Next, the n-MIS region is shielded with a resist, and ions are implanted using the dummy gate electrode 262, the SiO₂ film 266 and the SiN film 240 of the p-MIS region and the resist as masks to form the extension 206b and the pocket 208 in the p-MIS region.

Next, spacers are formed on the sides of SiN films 240 on the sides of the dummy gate electrodes 262 (Step S214). Here, in the same manner as in the first embodiment, SiO₂ films 242, SiN films 244, and SiO₂ films 246 are sequentially formed so as to embed the dummy gate electrodes 262 on the substrate 202 and the SiN films 240 on the sides thereof, and etched back to leave these insulating films only on the sides of the SiN films 240 on the both sides of the dummy gate electrodes 262. Thereby, the spacers 238 are formed.

Next, source-drain regions 210a and 210b are formed (Step S216). Here, after shielding the p-MIS region with a resist, ion implantation is performed using the dummy gate electrodes 262 and the spacers 238 on the sides thereof as masks to form the source-drain region 210a in the n-MIS region. Thereafter, in the same manner, after shielding the n-MIS region with a resist, ion implantation is performed using the dummy gate electrodes 262 and the spacers 238 on the sides thereof as masks to form the source-drain region 210b in the p-MIS region.

Next, an NiSi layer 212 is formed on the source-drain regions 210a and 210b (Step S218), and then, an SiN film 220 and an SiO₂ film 222 are laminated as interlayer insulating films (Steps S220 and S222). Thereafter, the SiO₂ film 222 is polished using CMP until the hard masks 264 are exposed.

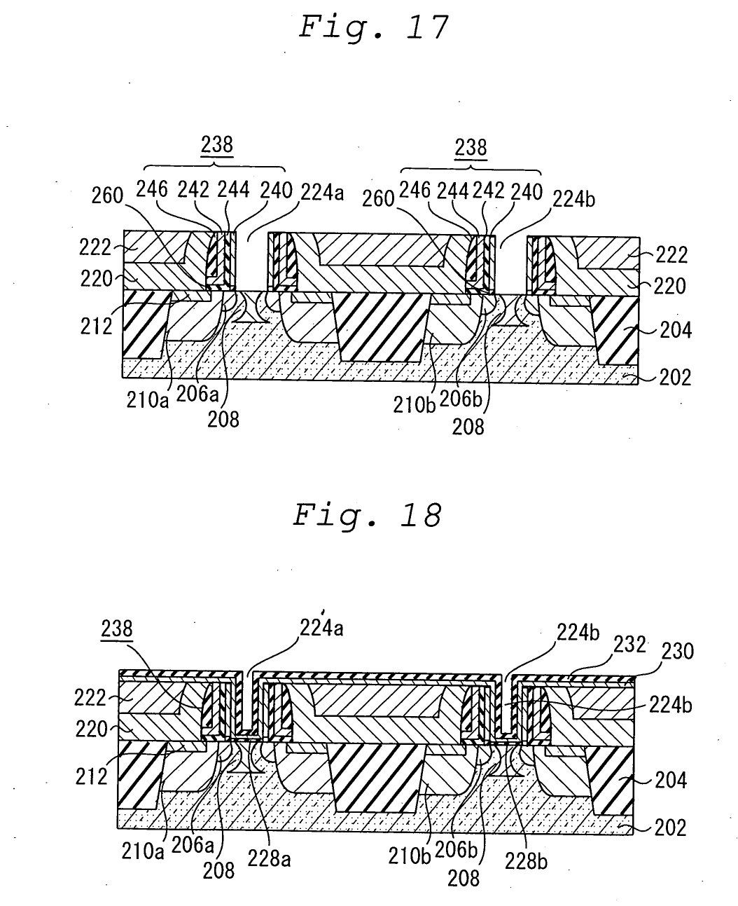

Next, as FIG. 17 illustrates, the hard masks 264, the dummy gate electrodes 262 and the dummy gate insulating films 260 are removed (Steps S224 to S228). Thereby, gate trenches 224a and 224b are formed in the SiN film 220 and the SiO₂ film 222.

Next, as FIG. 18 illustrates, thin SiO₂ films 228a and 228b of a thickness of about 0.8 nm are formed on the bottoms of the gate trenches 224a and 224b using thermal oxidation (Step S230), and then, an HfSiO film 230 is formed on the entire surface of exposed portion including the inner walls of the gate trenches 224a and 224b (Step S232). Here, the HfSiO film 230 is formed to have a thickness of about 2 nm using MOCVD. Furthermore, an SiN film 232 is formed (Step S234). The SiN film 232 is formed to have a thickness of about 0.5 nm using CVD.

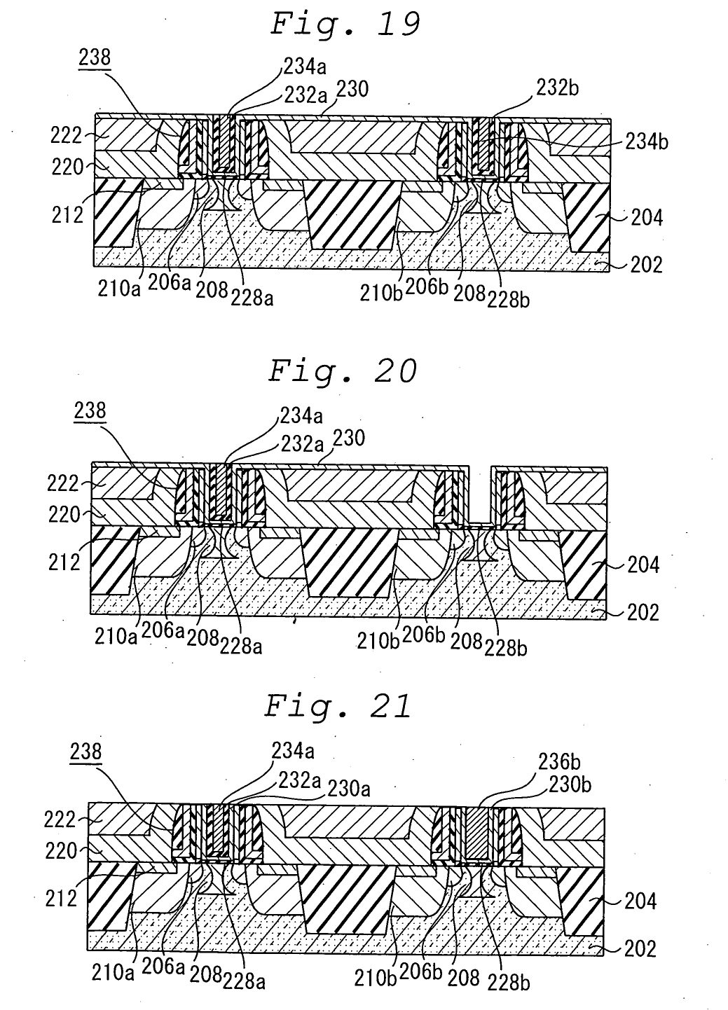

Thereafter, poly-Si films 234 are formed in the gate trenches 224a and 224b (Step S236). Thereafter, the poly-Si films 234 are polished until the surface of the HfSiO film 230 is exposed (Step S238). Thereby, as FIG. 19 illustrates, the gate electrode 234a is formed in the gate trench 224a in the n-MIS region.

Next, as FIG. 20 illustrates, the poly-Si film 234b of the p-MIS region is removed (Step S240). Here, the poly-Si film 234b is removed by etching, and at this time, the SiN film 232b on the inner wall of the gate trench 224b functions as an etching stopper film. Thereafter, the SiN film 232b damaged during etching is removed using wet etching (Step S242). Here, the SiN film 232b other than the SiN film 232a in the gate trench 224a in which the poly-Si film 234a is embedded is entirely removed.

Next, as FIG. 21 illustrates, W 236 is embedded in the gate trench 224b (Step S244). Furthermore, CMP is performed until the surface of the SiO₂ film 222 is exposed (Step S246) to form the gate insulating film 226b and the gate electrode 236b in the p-MIS region.

Thereafter, an SiO₂ film 248 is formed (Step S248), and in the same manner as in the first embodiment, contact plugs 250 are formed (Step S250), the formation of an interlayer insulating film 252 (Step S252), the formation of Cu wirings 254 (Step S254) and the like are performed to manufacture the semiconductor device in the second embodiment illustrated in FIG. 12.

According to the second embodiment, as described above, when a gate of a Damascene structure is formed, after removing the insulating film (SiN film 232b) damaged by etching, a gate electrode 236b is formed in the gate trench 224b. Therefore, both the n-MIS and the p-MIS can be transistors having gate insulating films of high film quality, and a semiconductor device having high device performance can be obtained.

### Third Embodiment

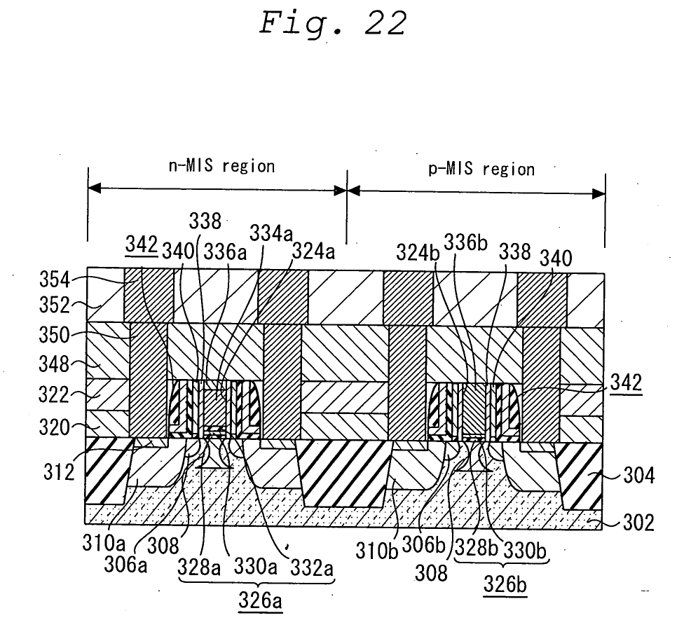

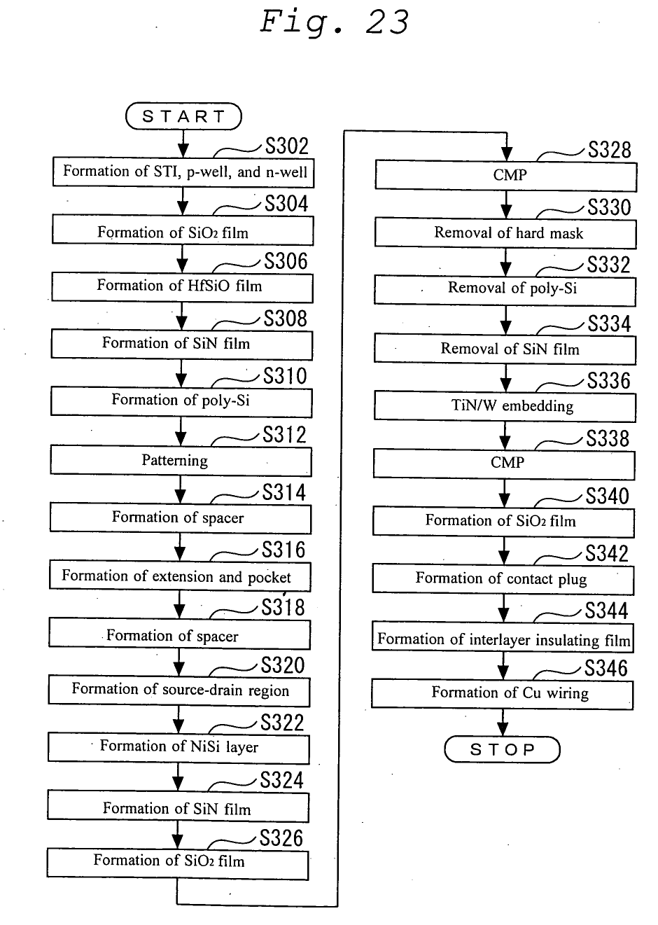

FIG. 22 is a schematic sectional view for illustrating a semiconductor device 300 according to the third embodiment of the present invention.

The semiconductor device 300 is similar to the semiconductor device 200 in the second embodiment, and has a Damascene gate structure.

In the cross section illustrated in FIG. 22, STIs 304 are formed in the substrate 302, and the substrate 302 is divided into an n-MIS region and a p-MIS region similar to the semiconductor device 200. N-type and p-type extensions 306a and 306b, respectively, are formed in the n-MIS region and the p-MIS region, respectively, and pockets 308 are formed so as to surround the undersides of the extensions 306a and 306b. In the both sides of the extensions 306a and 306b, n-type and p-type source-drain regions 310a and 310b are formed, respectively. On the surfaces of the source-drain regions 310a and 310b, NiSi layers 312 are formed.

On the substrate 302, an SiN film 320 and an SiO₂ film 322 are formed. Gate trenches 324a and 324b for forming gate electrodes are formed in the n-MIS region and the p-MIS region, respectively, so as to run through the SiN film 320 and the SiO₂ film 322.

A gate insulating film 326a is formed in the gate trench 324a of the n-MIS region. The gate insulating film 326a is a laminated film consisting of a thin SiO₂ film 328a, an HfSiO film 330a, and an SiN film 332a formed on the inner wall of the gate trench 324a. On the other hand, a gate insulating film 326b is formed in a gate trench 324b of the p-MIS region. The gate insulating film 326b is a laminated film consisting of a thin SiO₂ film 328b and an HfSiO film 330b formed on the inner wall of the gate trench 324b. Here, the thickness of the SiO₂ films 328a and 328b is about 0.8 nm, the thickness of the HfSiO films 330a and 330b is about 2 nm, and the thickness of the SiN film 332a is about 0.5 nm.

In the n-MIS region, a poly-Si film 334a and a TiN/W film 336a are laminated on the SiN film 332a in the gate trench 324a to form a gate electrode. P (phosphorus) ions are implanted into the poly-Si film 224a. On the other hand, in the p-MIS region, W is embedded in the gate trench 324b on the HfSiO film 330b through a TiN film to form a gate electrode consisting of TiN/W 336b.

On the both sides of each of gate trenches 324a and 324b, an SiO₂ film 338 and an SiN film 340 are formed, respectively, and spacers 342 are formed on the sides thereof. Each spacer 342 is composed of an SiO₂ film, an SiN film, and an SiO₂ film.

An SiO₂ film 348 is formed on the SiO₂ film 322, and contact plugs 350 running through the SiO₂ film 348, the SiO₂ film 322 and the SiN film 320, and extending to the NiSi layer 312 on the surfaces of the source-drain regions 310a and 310b are formed. An interlayer insulating film 352 is formed on the SiO₂ film 348 as in the first embodiment, and Cu wirings 354 are formed in the required locations.

FIG. 23 is a flow diagram for illustrating a method for manufacturing a semiconductor device 300 according to the third embodiment of the present invention. FIGS. 24 to 31 are schematic sectional views for illustrating the states in the steps for manufacturing the semiconductor device 300 in the third embodiment.

The method for manufacturing the semiconductor device 300 according to the third embodiment of the present invention will be specifically described referring to FIGS. 23 to 31.

First, in the same manner as Step S202 in the second embodiment, STIs 304, a p-well 356a, and an n-well 356b are formed on a substrate 302 (Step S302). An SiO₂ film 328, an HfSiO film 330, and an SiN film 332, which become material films for gate insulating film 326a or 326b in the third embodiment, are sequentially formed on the substrate 302 (Steps S304 to S308). Further, a poly-Si film 334 of a thickness of 80 nm is formed (Step S310), and P (phosphorus), which is an n-type impurity, is implanted.

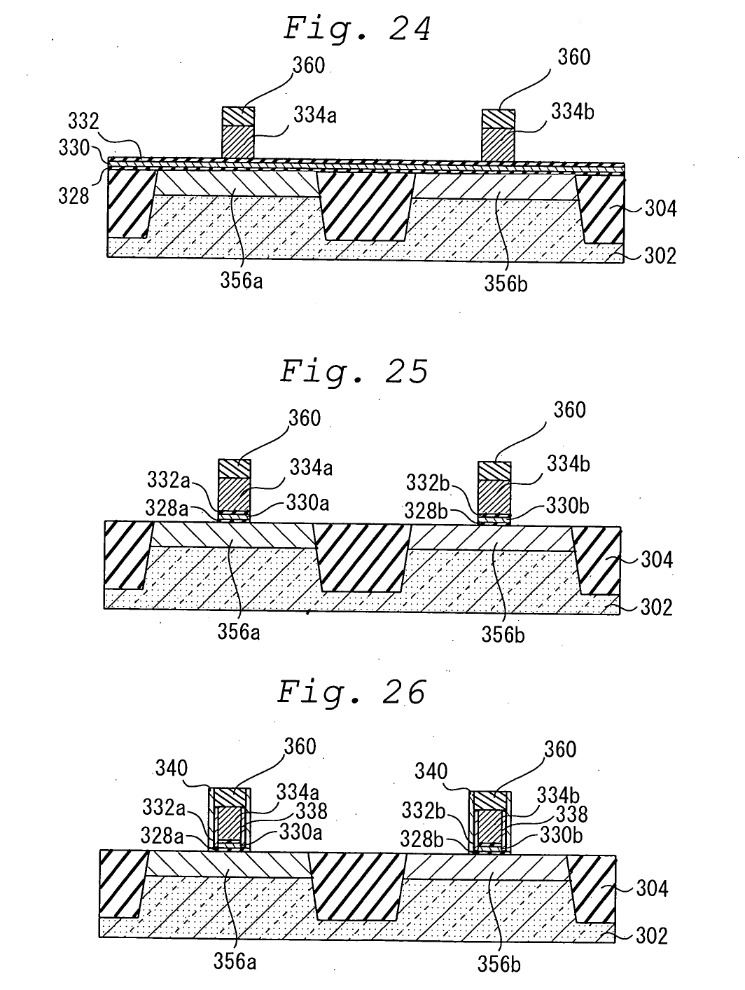

Next, as FIGS. 24 and 25 illustrate, a gate electrode is patterned (Step S312). In the patterning of the gate electrode, for example, an SiO₂ film of a thickness of 50 nm is formed on the poly-Si film 334. Next, resist masks are formed on the locations for forming gate electrodes using lithography, and the SiO₂ film is etched using the resist masks to form hard masks 360. The poly-Si film 334 is etched using the hard masks 360 as masks to form poly-Si films 334a and 334b as FIG. 24 illustrates.

Then, the SiN film 332, the HfSiO film 330, and the SiO₂ film 328 are etched using the hard masks 360 as the masks as FIG. 25 illustrates.

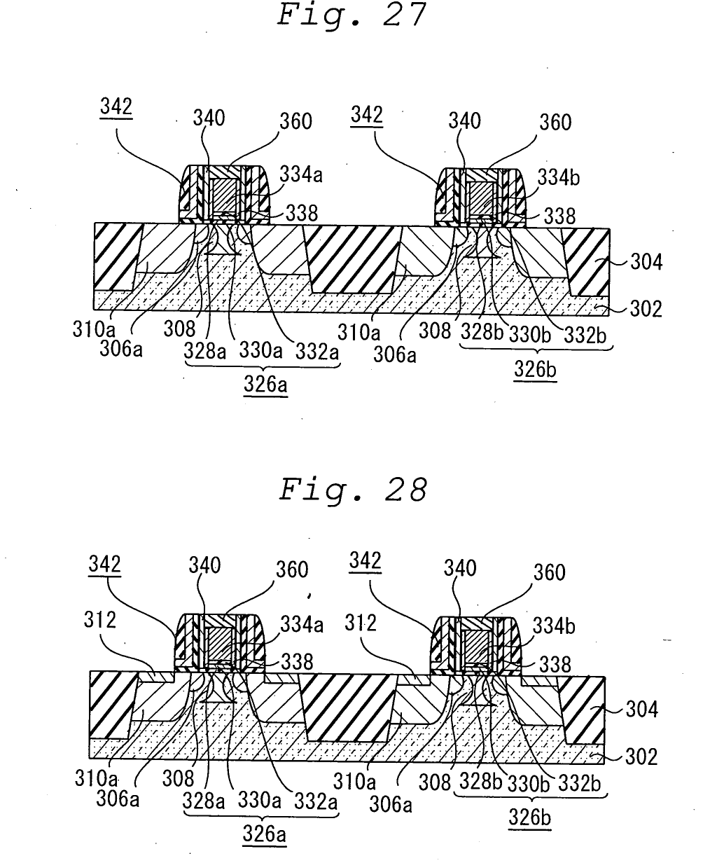

Next, as FIG. 26 illustrates, spacers each consisting of an SiO₂ film 338 and an SiN film 340 are formed on the sides of the poly-Si films 334a and 334b, gate insulating films 326a and 326b, and the hard masks 360 (Step S314). Specifically, SiO₂ films 338 of a thickness of about 2 nm, and SiN film 340 of a thickness of about 10 nm are deposited, and are etched back.

Next, in the same manner as Step S212 of the second embodiment, extensions 306a and 306b, and pockets 308 are formed (Step S316). In the impurity-ion implantation, the poly-Si films 334a and 334b, the SiO₂ films 338 and the SiN film 340 on the sides of the poly-Si films are used as the masks.

Next, in the same manner as Step S214, spacers 342 are formed on the sides of the SiN film 340, on the sides of the poly-Si films 334a and 334b and the hard masks 360 (Step S318). Here, each spacer 342 is composed of an SiO₂ film, an SiN film and an SiO₂ film as in the embodiments 1 and 2.

Next, in the same manner as Step S216, source-drain regions 310a and 310b are formed (Step S320). In the impurity-ion implantation into the source-drain regions 310a and 310b, the poly-Si films 334a or 334b, the spacers 342 on the sides of the poly-Si films, and the like are used as the masks.

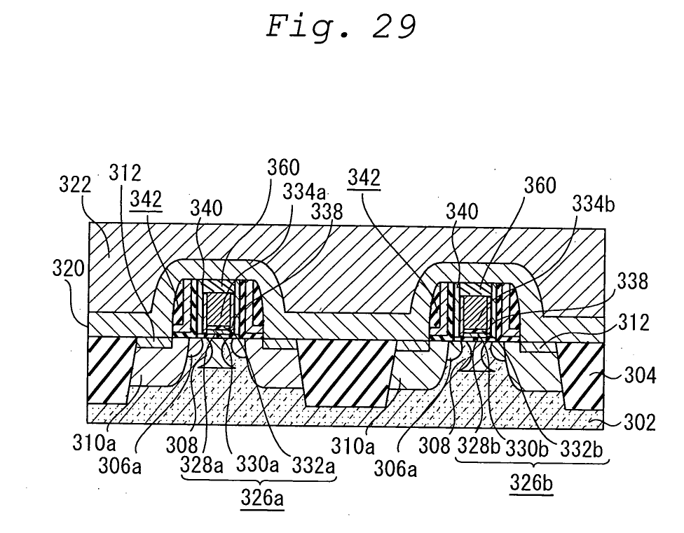

Next, as FIG. 28 illustrates, an NiSi layer 312 is formed on the source-drain regions 310a and 310b (Step S322). Thereafter, as FIG. 29 illustrates, an SiN film 320 and an SiO₂ film 322 are laminated as interlayer insulating films (Steps S324 and S326), and the SiO₂ film 322 is polished using CMP until the hard masks 360 are exposed (Step S328).

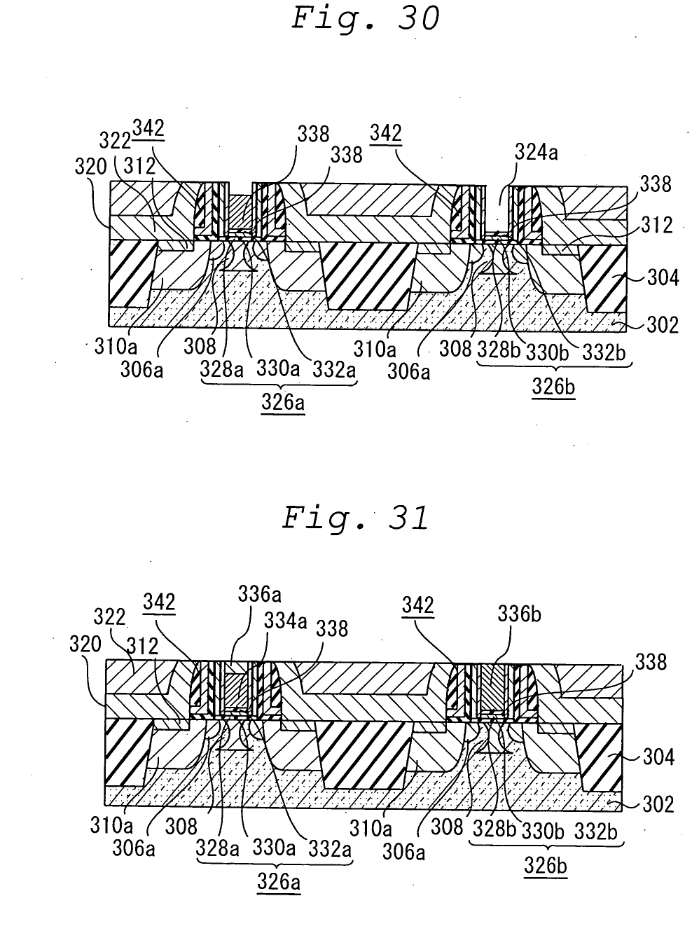

Next, as FIG. 30 illustrates, the hard masks 360 are selectively removed (Step S330). Thereafter, the poly-Si film 334b in the p-MIS region is removed (Step S332). In the removal of the poly-Si film 334b, etching is performed after forming a resist mask shielding the n-MIS region.

Next, the SiN film 332b damaged due to the removal of the poly-Si film 334b is removed (Step S334). Thereby, a gate trench 324b is formed in the p-MIS region.

Thereafter, as FIG. 31 illustrates, in the gate trench 334b, and a trench formed after the hard mask 360 on the poly-Si film 334a of the n-MIS region has been removed, TiN/W 336 is embedded (Step S336). Specifically, after forming a thin TiN film as a barrier film, W is embedded in the opening. Thereafter, the TiN/W 336 is polished using CMP to expose the surface of the SiO₂ film 322 (Step S338).

Thereafter, in the same manner as Steps S248 to S254 in the second embodiment, contact plugs 350 and the like are formed to form the semiconductor device 300 as shown in FIG. 22 (Step S340 to S346).

According to the third embodiment, as described above, when a gate of a Damascene structure is formed, a real gate insulating film is first formed, and then, an NiSi layer is formed. Thereafter, only the poly-Si film 334b, which is a dummy gate of the n-MIS region, is removed, and the TiN/W 336b is embedded as the gate electrode in this opening. Since the NiSi layer 312 is formed after the formation of the HfSiO film, which is a gate insulating film, the rise of the resistance of the NiSi layer 312 due to high-temperature treatment during the formation of the HfSiO film can be suppressed. Since the SiN film 332b damaged during the removal of the poly-Si film 334b in the p-MIS region is removed, a transistor having gate insulating film of high film quality can be formed, and a semiconductor device having favorable device performance can be obtained.

Since other aspects are the same as in the first and second embodiments, the description thereof will be omitted.

For example, the n-MIS and the p-MIS in the first, second and third embodiments fall under the “first transistor” and the “second transistor” of the present invention, respectively. For example, the gate electrodes 120a and 234a in the first and second embodiments, and the poly-Si film 334a and the TiN/W 336a in the third embodiment fall under the “first gate electrode” of the present invention; and the gate electrodes 122b, 236b, and the TiN/W 336b fall under the “second gate electrode” of the present invention. For example, the gate insulating films 112a, 226a, and 326a in the first, second and third embodiments fall under the “first gate insulating film” of the present invention; and the gate insulating films 112b, 226b, and 326b fall under the “second gate insulating film” of the present invention. The HfSiO films 116a, 116b, 230a, 230b, 330a, and 330b in the first, second and third embodiments fall under the “high-dielectric-constant films” of the present invention; and the SiN films 118a, 232a, and 332a fall under the “first insulating films” of the present invention.

In the first embodiment, for example, by carrying out Steps S106 and S108, the “step for forming a high-dielectric-constant film” and the “step for forming a first insulating film” of the present invention are carried out, respectively. In the first embodiment, for example, by carrying out Steps S110 to S116, the “step for forming a first gate electrode” of the present invention is carried out. For example, by carrying out Steps S116 and S118, the “step for removing the first gate electrode” and the “step for removing the first insulating film” of the present invention are carried out, respectively. For example, by carrying out Steps S120 to S124, a second gate electrode” of the present invention is carried out.

In the second embodiment, for example, by carrying out Steps S204 to S208, the “step for forming a dummy electrode” of the present invention is carried out. For example, by carrying out Steps S212 and S216, the “step for forming an impurity-diffusion layer” is carried out. By carrying out Steps S220 to S222, the “step for forming an interlayer insulating film” is carried out; and by carrying out Steps S224 to S228, the “step for forming an opening” is carried out. For example, by carrying out Step 230, the “step for forming a high-dielectric-constant film” and the “step for forming a first insulating film” are carried out. For example, by carrying out Step 232, the “step for embedding a first material” is carried out; and by carrying out Steps S236 and S238, the “step for removing the first material” and the “step for removing the first insulating film” are carried out, respectively. By carrying out Step S240, the “step for embedding a second material” is carried out.

In the third embodiment, for example, by carrying out Steps S306 and S308, the “step for forming a gate insulating film” of the present invention is carried out; by carrying out Steps S310 to S312, the “step for forming a first gate insulating film” is carried out; by carrying out Steps S316 and S320, the “step for forming an impurity-diffusion layer” is carried out; by carrying out Step S322, the “step for forming a silicide layer” is carried out; by carrying out Steps S324 and S326, the “step for forming an interlayer insulating film” is carried out; by carrying out Step S332, the “step for forming an opening” is carried out; by carrying out Step S334, the “step for removing the first insulating film” are carried out; and by carrying out Step S336, the “step for forming a second gate electrode” is carried out.

The features and the advantages of the present invention as described above may be summarized as follows.

According to one aspect of the present invention, a first insulating film is formed between a first gate electrode having a first work function and a high-dielectric-constant film. The high-dielectric-constant film or a second insulating film thinner than the first insulating film is formed immediately under a second gate electrode having a second work function. Specifically, here, the gate insulating film immediately under the second gate electrode is a high-dielectric-constant film, or a second insulating film formed anew after removing the first gate electrode or removed the surface of the fist insulating film. Therefore, since a gate insulating film damaged when the unnecessary portion of the first gate electrode can be once removed, the damage of the gate insulating film can be suppressed, and a high-reliability dual-gate structure can be realized.

Obviously many modifications and variations of the present invention are possible in the light of the above teachings. It is therefore to be understood that within the scope of the appended claims the invention may by practiced otherwise than as specifically described.

The entire disclosure of a Japanese Patent Applications No. 2004-076978, filed on Mar. 17, 2004 and No. 2004-282180, filed on Sep. 28, 2004 including specifications, claims, drawings and summaries, on which the Convention priority of the present applications are based, are incorporated herein by references in their entirety.

1. A semiconductor device comprising:
a first transistor including a first gate electrode composed of a first material having a first work function, and a first gate insulating film; and
a second transistor including a second gate electrode composed of a second material having a second work function, and a second gate insulating film, wherein
said first gate insulating film includes:
a high-dielectric-constant film, and
a first insulating film on said high-dielectric-constant film; and
said second gate insulating film includes at least said high-dielectric-constant film.

2. The semiconductor device according to claim 1, wherein
said second gate insulating film includes a second insulating film on said high-dielectric-constant film, and
said second insulating film is thinner than said first insulating film.

3. The semiconductor device according to claim 1, wherein
said first material includes polycrystalline silicon; and
said second material has a work function at least 0.55 eV larger than the electron affinity of silicon.

4. The semiconductor device according to claim 1, wherein said high-dielectric-constant film includes at least hafnium and oxygen.

5. A method of manufacturing a semiconductor device comprising:
forming a high-dielectric-constant film on each of a first active region and a second active region of a substrate;
forming a first insulating film on said high-dielectric-constant film in each of said first and second active regions;
forming a first gate electrodes composed of a first material having a first work function, on said first insulating film on each of said first and second active regions;
removing said first gate electrode from said second active region;
removing said first insulating film from said second active region by etching, using said first gate electrode as a mask; and
forming a second gate electrodes composed of a second material having a second work function, on said second active region.

6. The methods of manufacturing a semiconductor device according to claim 5, including removing said first insulating film removing under conditions removing only a part of said first insulating film.

7. The method of manufacturing a semiconductor device according to claim 5, wherein
said first material is polycrystalline silicon; and
said second material has a work function at least 0.55 eV larger than the electron affinity of silicon.

8. The method of manufacturing a semiconductor device according to claim 5, wherein said high-dielectric-constant film contains at least hafnium and oxygen.

9. A method of manufacturing a semiconductor device comprising:
forming a dummy gate insulating film and a dummy gate electrode on each of a first active region and a second active regions of a substrate;
forming an impurity diffusion region in each of a first active region and a second active region, using each of said dummy gate electrodes as a mask;
forming an interlayer insulating film embedding said dummy gate insulating films and said dummy gate electrodes;
forming openings in said interlayer insulating film in each of said first active region and said second active region, by removing said dummy gate insulating films and said dummy gate electrodes from said interlayer insulating film;
forming a high-dielectric-constant film at least in the openings in each of said first active region and said second active region;
forming a first insulating film on said high-dielectric-constant film in each of said first active region and said second active region;
embedding a first material having a first work function in the openings in each of said first active region and said second active region;
removing said first material embedded in said opening in said second active region;
removing said first insulating film other than in the opening of said first active region; and
embedding a second material having a second work function in the opening of said second active region.

10. The method of manufacturing a semiconductor device according to claim 9, including removing said first insulating film under conditions removing only a part of said first insulating film in said second active region.

11. The method of manufacturing a semiconductor device according to claim 9, wherein
said first material is polycrystalline silicon; and
said second material has a work function at least 0.55 eV larger than the electron affinity of silicon.

12. The method of manufacturing a semiconductor device according to claim 9, wherein said high-dielectric-constant film contains at least hafnium and oxygen.

13. A method of manufacturing a semiconductor device comprising:
forming a gate insulating film including at least a high-dielectric-constant film, and a first insulating film on said high-dielectric-constant film on each of a first active region and a second active region of a substrate;
forming a first gate electrodes composed of a material having a first work function, on said gate insulating film in each of said first active region and said second active region;
forming an impurity diffusion region in each of said first active region and said second active region, using each of said first gate electrodes as a mask;
forming silicide layers on said impurity diffusion region;
forming an interlayer insulating film, embedding said first gate insulating films and said first gate electrodes;
forming an opening in said interlayer insulating film in said second active region by removing said first gate electrode of said second active region from said interlayer insulating film;
removing said first insulating film at least where exposed on the bottom of said opening; and
embedding a second gate electrodes composed of a material having a second work function, in said opening.

14. The method of manufacturing a semiconductor device according to claim 13, including removing said first insulating film under conditions removing only a part of said first insulating film.

15. The method of manufacturing a semiconductor device according to claim 13, wherein
said first material is polycrystalline silicon; and
said second material has a work function at least 0.55 eV larger than the electron affinity of silicon.

16. The method of manufacturing a semiconductor device according to claim 13, wherein said high-dielectric-constant film contains at least hafnium and oxygen.
